(19) United States
(12) Patent Application Publication
(10) Pub. No.: US 2021/0136912 A1
(43) Pub. Date: May 6, 2021

(54) STRETCHABLE WIRING BODY AND STRETCHABLE BOARD

(71) Applicant: Fujikura Ltd., Tokyo (JP)

(72) Inventor: Kazutoshi Koshimizu, Chiba (JP)

(73) Assignee: Fujikura Ltd., Tokyo (JP)

(21) Appl. No.: 16/492,322

(22) PCT Filed: Mar. 6, 2018
(86) PCT No.: PCT/JP2018/008586

§ 371 Date: Sep. 9, 2019

(30) Foreign Application Priority Data
Mar. 9, 2017 (JP) 2017-044581

(51) Int. Cl. H05K 1/02; H05K 1/09

(52) U.S. Cl. CPC H05K 1/0283; H05K 1/092; H05K 2201/09045; H05K 2201/0212; H05K 2201/0215

(57) ABSTRACT

A stretchable wiring body includes: a conductor that includes a binder and conductive particles dispersed in the binder; and soft resins that are embedded in the binder and are softer than the binder. The conductive particles are not covered with the soft resins.

### CROSS-REFERENCE TO RELATED APPLICATIONS

For designated countries that are permitted to be incorporated by reference in the literature, the contents of Patent Application No. 2017-044581, filed with Japan Patent Office on Mar. 9, 2017 are incorporated herein by reference and are regarded as a part of the description of this specification.

### TECHNICAL FIELD

The present invention relates to a stretchable wiring body and a stretchable board.

### BACKGROUND

There is known, as a stretchable board, one including a stretchable substrate and a conductive pattern, which is formed on the stretchable substrate and contains conductive fine particles and an elastomer, in which the elastomer is not cross-linked by a cross-linking agent (for example, see Patent Document 1).

### PATENT DOCUMENT

Patent Document 1: JP 2014-236103 A

In general, if the conductive pattern cannot follow the deformation of the stretchable substrate, cracks are generated in the conductor pattern and the conductivity of the conductor pattern is degraded.

On the other hand, it is considered that generation of cracks in the conductor pattern due to the deformation of the stretchable substrate is suppressed by providing high flexibility without cross-linking an elastomer by a cross-linking agent as in the above-described stretchable board. However, in this case, the Young's modulus of the elastomer is decreased, and thus durability is lacking.

### SUMMARY

One or more embodiments of the present invention provide a stretchable wiring body and a stretchable board in which durability can be improved while degradation in conductivity is suppressed.

A stretchable wiring body according to one or more embodiments of the present invention is a stretchable wiring body including a conductor part which includes a binder and conductive particles dispersed in the binder, and soft resins which are embedded in the binder and are relatively softer than the binder, in which the conductive particles are not covered with the soft resins.

In the stretchable wiring body according to one or more embodiments of the present invention, the following Formula (1) may be satisfied:

D>L (1)

in the above Formula (1), D is a particle diameter of the conductive particle, and L is a length of the soft resin.

In the stretchable wiring body according to one or more embodiments of the present invention, a shape of the soft resin may be a granular shape.

In the stretchable wiring body according to one or more embodiments of the present invention, the soft resins may be dispersed in the binder.

A stretchable board according to one or more embodiments of the present invention is a stretchable board including the stretchable wiring body described above, and a stretchable substrate on which the conductor part is disposed.

In the stretchable board according to one or more embodiments of the present invention, at least a part of the soft resins may be protrusions each of which is a protruding portion of the stretchable substrate.

According to one or more embodiments of the present invention, since the soft resin can follow the deformation of the wiring body, generation of cracks in the conductor part can be suppressed. According to this, degradation in the conductivity of the conductor part can be suppressed.

Further, since the soft resins are embedded in the binder, the soft resins are hardly exposed to the outside. Therefore, degradation of the soft resin can be suppressed, and durability of the whole stretchable board can be improved.

### BRIEF DESCRIPTION OF DRAWINGS

FIG. 1 is a perspective view illustrating a stretchable board, which connects both external circuits, according to one or more embodiments of the present invention;

FIG. 2 is a cross-sectional view of the stretchable board taken in a height direction along an extending direction according to one or more embodiments of the present invention;

FIG. 3 is a partially enlarged view of a conductor part and soft resins according to one or more embodiments of the present invention;

FIG. 4 is a diagram for describing a particle diameter of a particle according to one or more embodiments of the present invention;

FIG. 5A is a partially enlarged view of a conductor part according to a comparative example and illustrates a state before the stretchable board is stretched according to one or more embodiments of the present invention, and FIG. 5B is a partially enlarged view of the conductor part according to the comparative example and illustrates a state after the stretchable board is stretched according to one or more embodiments of the present invention;

FIG. 6A is a partially enlarged view of the conductor part according to one or more embodiments of the present invention and illustrates a state before the stretchable board is stretched, and FIG. 6B is a partially enlarged view of the conductor part according to one or more embodiments of the present invention and illustrates a state after the stretchable board is stretched;

FIG. 7 is a cross-sectional view of a stretchable board according to one or more embodiments of the present invention taken in a height direction;

FIG. 8A is a plan view illustrating the stretchable board according to one or more embodiments of the present invention, and FIG. 8B is a plan view illustrating a modified example of the stretchable board according to one or more embodiments of the present invention;

FIG. 9 is a cross-sectional view of a stretchable board according to still one or more embodiments of the present invention taken in a height direction; and

FIG. 10A is a plan view illustrating the stretchable board according to still one or more embodiments of the present invention, and FIG. 10B is a plan view illustrating a modified example of the stretchable board according to still one or more embodiments of the present invention.

### DETAILED DESCRIPTION

Hereinafter, embodiments of the present invention will be described on the basis of the drawings.

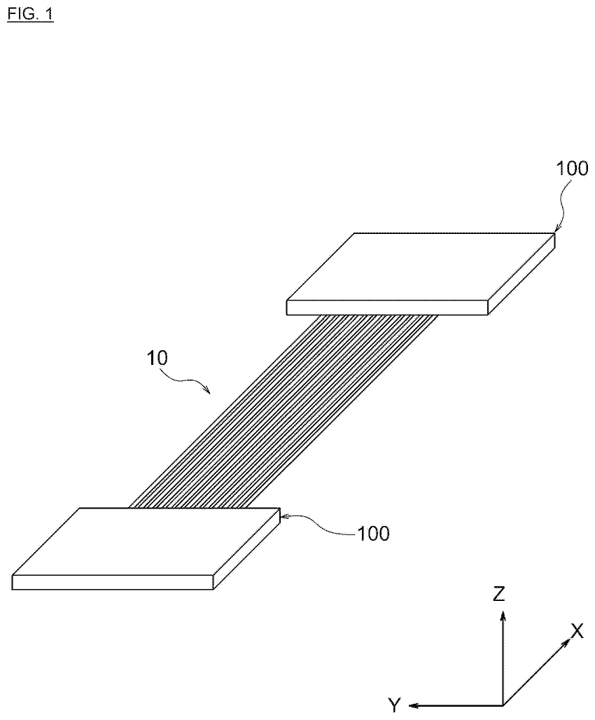

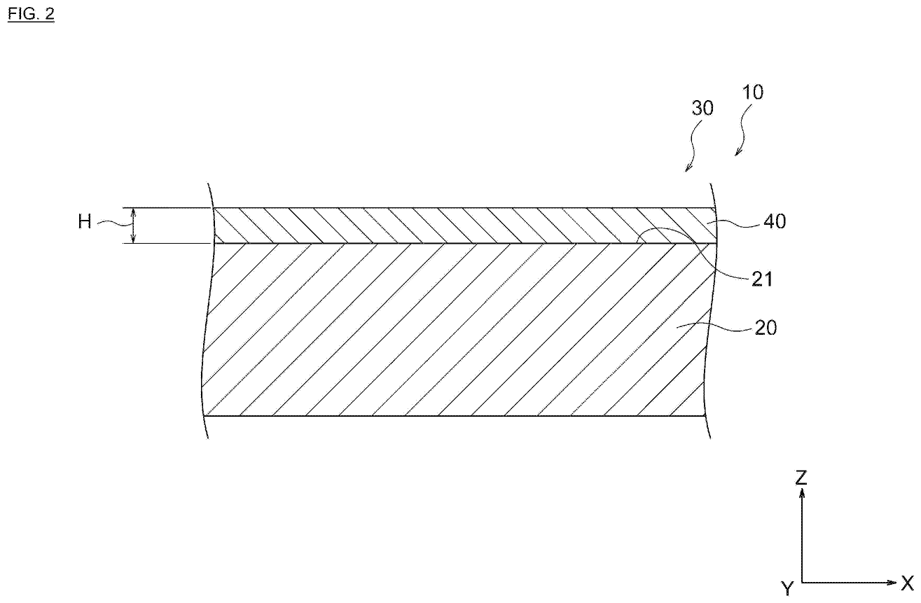

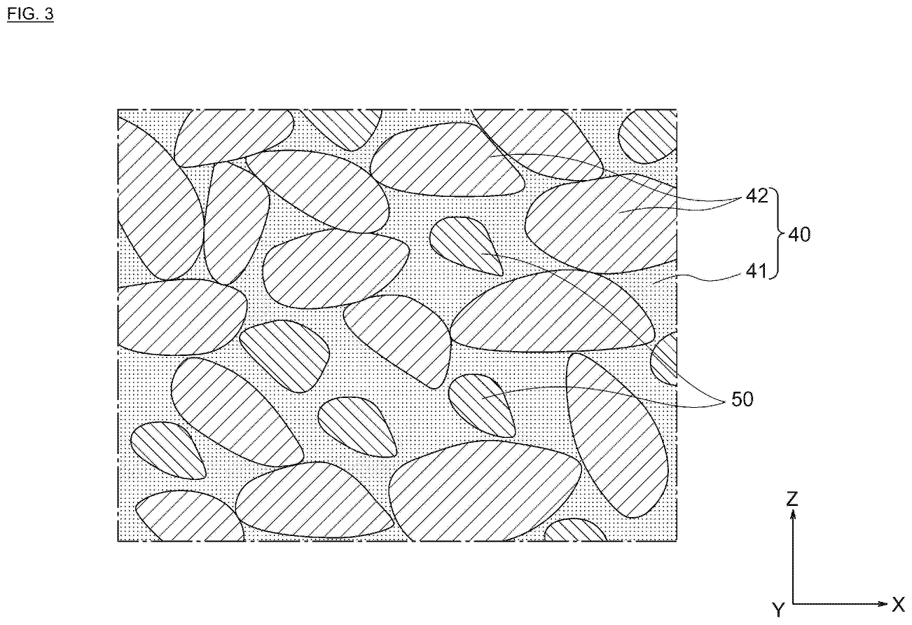

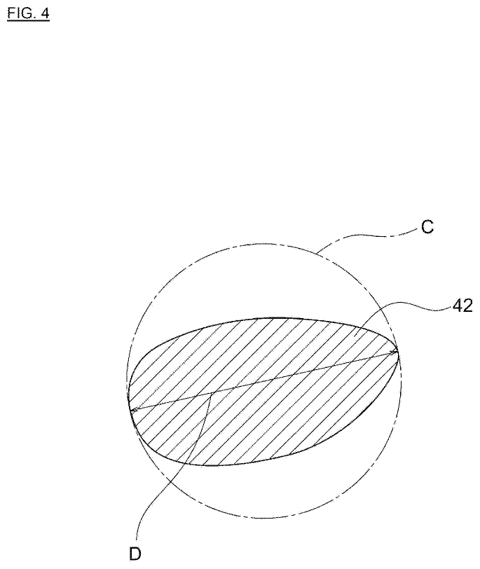

FIG. 1 is a perspective view illustrating a stretchable board, which connects both external circuits, according to one or more embodiments of the present invention, FIG. 2 is a cross-sectional view of the stretchable board taken in a height direction along an extending direction according to one or more embodiments of the present invention, FIG. 3 is a partially enlarged view of a conductor part and soft resins according to one or more embodiments of the present invention, and FIG. 4 is a diagram for describing a particle diameter of a particle according to one or more embodiments of the present invention.

A stretchable board 10 illustrated in FIG. 1 is a wiring board which electrically connects external circuits 100 such as a rigid board and a flexible printed circuit board (FPC) and has stretching properties. Such a stretchable board 10 is, although not particularly limited, for example, applied to parts, which need bending properties or stretching properties, such as a movable portion or bend portion of industrial robots etc. and internal wirings of laptop personal computers. This stretchable board 10 includes a stretchable substrate 20 and a stretchable wiring body 30 as illustrated in FIG. 2.

The stretchable substrate 20 is a plate-like member which is formed in a rectangular shape and has stretching properties. As this stretchable substrate 20, for example, an elastic sheet (elastomer sheet) or a fabric cloth formed by fibers can be used. Examples of an elastomer which can be used include natural rubber, styrene-butadiene rubber, butadiene rubber, chloroprene rubber, butyl rubber, nitrile rubber, ethylene-propylene rubber, acrylic rubber, urethane rubber, silicone rubber, and fluoro-rubber. Other elastomer materials may be used. Examples of fibers which can be used include rayon, nylon, polyester, acrylic, polyurethane, vinylon, polyethylene, Nafion (registered trademark), aramid, and cotton.

The Young's modulus of the stretchable substrate 20 is 0.1 to 35 MPa according to one or more embodiments of the present invention. Further, the maximum elongation rate of the stretchable substrate 20 is 5 to 50% according to one or more embodiments of the present invention. The maximum elongation rate is the maximum value of the elongation rate in which each configuration can be elastically deformed. Further, the fracture elongation rate of the stretchable substrate 20 is 50% or more according to one or more embodiments of the present invention. Furthermore, the thickness of the stretchable substrate 20 is 20 to 300 μm according to one or more embodiments of the present invention.

The stretchable wiring body 30 has stretching properties and, as illustrated in FIG. 2, is disposed on the stretchable substrate 20. This stretchable wiring body 30 includes a conductor part (conductor) 40 and soft resins 50 as illustrated in FIG. 3.

The conductor part 40 is configured with arbitrary patterns such as straight line patterns and curved line patterns and is disposed on the stretchable substrate 20 (specifically, a main surface 21). This conductor part 40 includes a binder 41 and conductive particles 42. The binder 41 is a binder resin and is contained in the conductor part 40 in order to bind the plurality of conductive particles 42 contained in the conductor part 40 and to stabilize conductive particles 42 such that the conductive particles 42 are not condensed again when the stretchable board 10 is deformed. The conductor part 40 has stretching properties similarly to the stretchable substrate 20, and in this case, a synthetic resin or an elastomer is used as the binder 41 according to one or more embodiments of the present invention. According to this, even when deformation due to external force such as stretching or bending is applied to the stretchable board 10, properties that the shape returns to the original shape are obtainable by eliminating the external force.

Examples of the binder 41 which can be used include a polyester resin, a polyurethane resin, an acrylic resin, acrylic rubber, urethane rubber, nitrile rubber, silicone rubber, fluoro-rubber, and a complex of two or more kinds thereof. Such a binder 41 may be a crosslinkable resin composition or non-crosslinkable resin composition.

The Young's modulus of the binder 41 is 1 to 35 MPa according to one or more embodiments of the present invention. Further, the maximum elongation rate of the binder 41 is 5 to 50% according to one or more embodiments of the present invention. Furthermore, the fracture elongation rate of the binder 41 is 50% or more according to one or more embodiments of the present invention.

The conductive particles 42 are dispersed in the binder 41. As the conductive particles 42, a metal material made of a metal such as gold, silver, platinum, ruthenium, lead, tin, zinc, or bismuth, or an alloy thereof or a non-metal material such as carbon can be used. The shape of the conductive particles 42 is a scaly shape or an irregular shape according to one or more embodiments of the present invention. The abundance ratio of the conductive particle 42 in the stretchable wiring body 30 is 50% or more according to one or more embodiments of the present invention. The abundance ratio in the stretchable wiring body 30 is a ratio of the area of the conductive particles 42 to the total cross-sectional area of the stretchable wiring body 30 in the cross-section of the stretchable wiring body 30 taken along the height direction.

A particle diameter D of the conductive particle 42 is 0.5 to 20 μm according to one or more embodiments of the present invention. The particle diameter of the conductive particle 42 is an average particle diameter and, as illustrated in FIG. 4, is an average value of the diameter D of an imaginary circle C circumscribing the conductive particle 42.

The soft resin 50 is a resin composition that is relatively softer than the binder 41. This soft resin 50 is provided to improve stretching properties of the conductor part 40 so that the conductor part 40 can follow the deformation of the stretchable substrate 20.

This soft resin 50 is an elastomer and has stretching properties. As such a soft resin 50, the same material as the binder 41 mentioned above can be used. For example, the binder 41 and the soft resin 50 may be made of the same material. In this case, a plasticizer or the like is added to the soft resin 50 in order to soften the soft resin 50 more than the binder 41.

The Young's modulus of this soft resin 50 is relatively lower than the Young's modulus of the binder 41 according to one or more embodiments of the present invention. The Young's modulus of such a soft resin 50 is 0.1 to 20 MPa according to one or more embodiments of the present invention.

This soft resins 50 are embedded in the binder 41. In one or more embodiments of the present invention, the shape of the soft resin 50 is a granular shape. The soft resins 50 having a granular shape exist while being dispersed in the binder. As the shape of the soft resin 50 having a granular shape, for example, similarly to the conductive particles 42, the shape may be a scaly shape or an irregular shape. A length L of such a soft resin 50 is 0.5 to 10 μm in an unloaded state according to one or more embodiments of the present invention. The length L of the soft resin 50 is an average value of the maximum lengths of the soft resins 50. In one or more embodiments of the present invention, since the soft resin 50 has a granular shape, the particle diameter of soft resin particles is used as the length L of the soft resin 50.

From the viewpoint of suppressing generation of cracks in the conductor part 40 and propagation and development of the generated cracks, the relation between the particle diameter D of the conductive particle 42 and the length L of the soft resin 50 is set to satisfy the following Formula (2) according to one or more embodiments of the present invention.

D>L (2)

In the binder 41, the conductive particles 42 and the soft resins 50 are separated and dispersed without agglutinating to each other. For this reason, the conductive particles 42 are not covered with the soft resins 50. The conductive particles 42 and the soft resins 50 may be in contact with each other, but the outer circumferences of the conductive particles 42 are not completely covered with the soft resins 50. From the viewpoint of suppressing degradation in conductivity of the conductor part 40 while improving the stretching properties of the conductor part 40, the abundance ratio of the soft resin 50 in the stretchable wiring body 30 is 1 to 50% according to one or more embodiments of the present invention.

Such a conductor part 40 is formed by applying a conductive paste onto the main surface 21 of the stretchable substrate 20 and curing the conductive paste. Specific examples of such a conductive paste may include conductive pastes configured by mixing the binder 41, the conductive particles 42, and the soft resin 50 mentioned above with water or solvent and various additives (such as an antioxidant, a flame retardant, and a softening agent). As the solvent contained in the conductive paste, for example, butyl cellosolve acetate, carbitol acetate, butyl carbitol acetate, dipropylene glycol monobutyl ether, diethylene glycol monoethyl ether, cyclohexanone, isophorone, terpineol, and the like can be used.

Examples of an application method of the conductive paste may include a dispensing method, an ink jet method, and a screen printing method. Alternatively, examples thereof may include a slit coating method, a bar coating method, a blade coating method, a dip coating method, a spray coating method, and a spin coating method. Further, examples of a curing method of the conductive paste may include a heating treatment and irradiation of energy rays such as infrared light, ultraviolet light, and laser light. As the curing treatment of the conductive paste, only drying may be performed.

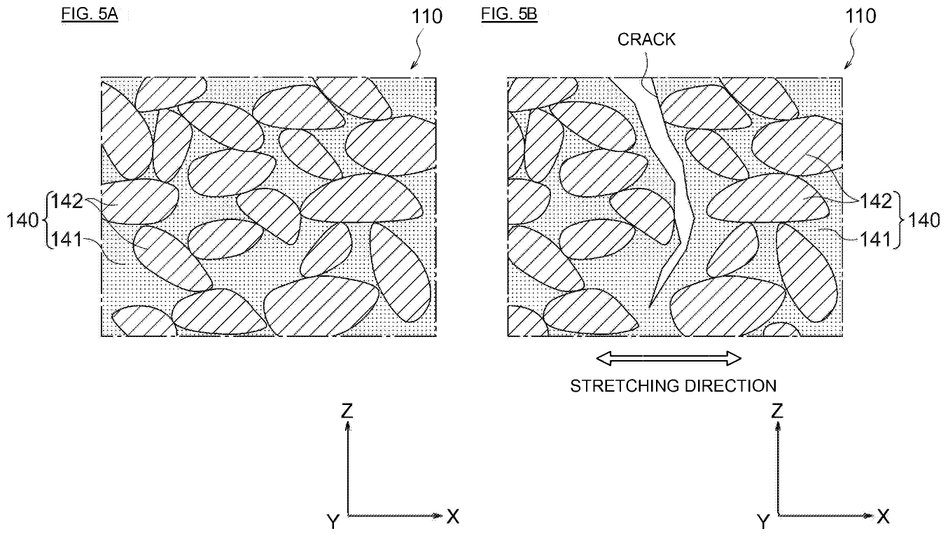

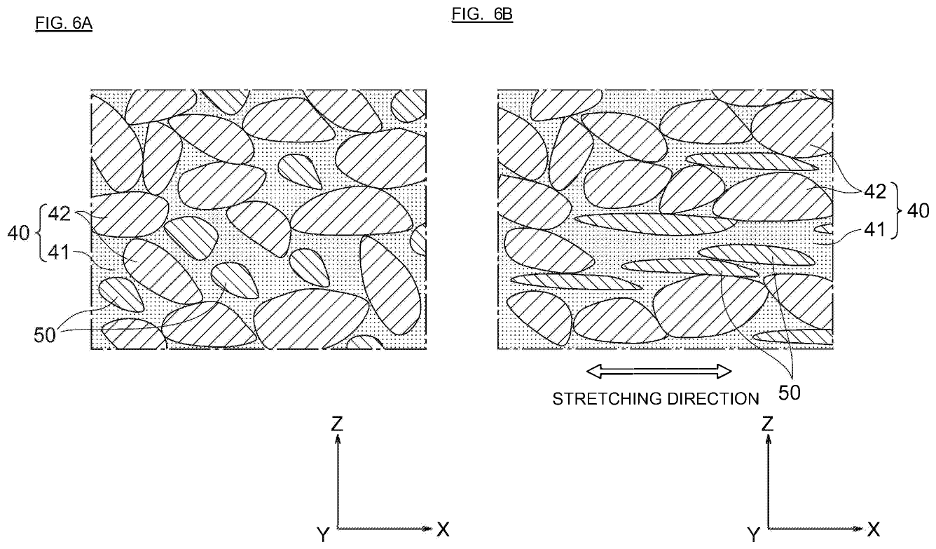

The operation of the stretchable wiring body 30 and the stretchable board 10 according to one or more embodiments of the present invention will be described. FIG. 5A is a partially enlarged view of a conductor part according to a comparative example and illustrates a state before the stretchable board is stretched according to one or more embodiments of the present invention, and FIG. 5B is a partially enlarged view of the conductor part according to the comparative example and illustrates a state after the stretchable board is stretched according to one or more embodiments of the present invention. Further, FIG. 6A is a partially enlarged view of the conductor part according to one or more embodiments of the present invention and illustrates a state before the stretchable board is stretched, and FIG. 6B is a partially enlarged view of the conductor part according to one or more embodiments of the present invention and illustrates a state after the stretchable board is stretched.

In a stretchable board 110 according to a first comparative example, as illustrated in FIG. 5A, a binder resin 141 and conductive particles 142 are included in a conductor part 140. In a case where external force is applied to this stretchable board 110, in the conductor part 140, the binder resin 141 is stretched to follow the deformation of the stretchable board 110 so that generation of cracks in the conductor part 140 can be suppressed.

Herein, when the Young's modulus of the resin composition such as a binder increases, the maximum elongation rate and the fracture elongation rate tend to be accordingly degraded, and stiffness tends to be improved. On the other hand, when the Young's modulus is lowered, the maximum elongation rate and the fracture elongation rate tend to be accordingly improved, and stiffness tends to be degraded. When the stretching properties of the conductor part 140 are improved by lowering the Young's modulus of the binder 141 in order for the conductor part 140 to easily follow the deformation of the stretchable board 110, the stiffness of the binder 141 is degraded, and further, the durability of the whole conductor part 140 is degraded. On the other hand, when the stiffness of the binder 141 is improved by increasing the Young's modulus of the binder 141 in order to improve the durability of the whole stretchable board 110, the stretching properties of the binder 141 are impaired. Thus, as illustrated in FIG. 5B, the conductor part 140 cannot follow the deformation of the stretchable board 110 and a crack is generated in the conductor part 140.

Further, in a case where the stretching properties of the conductor part 140 are improved by lowering the Young's modulus of the binder 141 in order for the conductor part 140 to easily follow the deformation of the stretchable board 110, the stretching of the conductor part 140 occurs uniformly in the whole region. For this reason, in a state where the stretchable board 110 is deformed, the conductive particles 142 are separated from each other, a contact resistance between the conductive particles 142 increases, or the conductivity of the conductor part 140 is degraded.

In contrast to this comparative example, in one or more embodiments of the present invention, as illustrated in FIG. 6A, the soft resins 50, which are relatively softer than the binder 41, are embedded in the binder 41. In this case, since the soft resins 50 can follow the deformation of the stretchable board 10, the stretching properties of the conductor part 40 can be improved. Meanwhile, when the soft resins 50 are embedded in the binder 41, the soft resins 50 are difficult to expose to the outside of the stretchable board 10. Therefore, degradation of the soft resins 50 which are poor in durability can be suppressed, and thus the durability of the whole stretchable wiring body 30 can be improved.

Further, in one or more embodiments of the present invention, as illustrated in FIG. 6B, since the soft resins 50 are deformed easier than the binder 41 in the deformation of the stretchable board 10, the whole region of the conductor part 40 can be prevented from being uniformly stretched. According to this, when the stretchable board 10 is deformed, degradation in conductivity of the conductor part 40 can be suppressed.

Further, in one or more embodiments of the present invention, the conductive particles 42 are not covered with the soft resins 50. For this reason, even when external force is applied to the stretchable board 10 to deform the conductor part 40 and change the arrangement of the conductive particles 42, the conductive particles 42 can be in contact with each other. In this case, since a new conduction path is generated in the conductor part 40, the conductivity of the conductor part 40 can be improved.

Further, in one or more embodiments of the present invention, the relation between the diameter D of the conductive particle 42 and the diameter L of the soft resin 50 satisfies the above Formula (2). Therefore, it is possible to suppress generation of cracks in the conductor part 40 along the surface of the soft resin 50 and propagation and development of the generated cracks.

Further, in one or more embodiments of the present invention, since the soft resin 50 has a granular shape, the stretching properties of the conductor part 40 can be easily exhibited regardless of the direction of external force to be applied to the stretchable wiring body 30.

Further, in one or more embodiments of the present invention, the granular soft resins 50 are dispersed in the binder 41. In this case, since the granular soft resins 50 exist in the whole conductor part 40, stretching properties can be provided to the whole stretchable wiring body 30.

The “stretchable board 10” corresponds to an example of the “stretchable board” in one or more embodiments of the present invention, the “stretchable substrate 20” corresponds to an example of the “stretchable substrate” in one or more embodiments of the present invention, the “stretchable wiring body 30” corresponds to an example of the “stretchable wiring body” in one or more embodiments of the present invention, the “conductor part 40” corresponds to an example of the “conductor part” in one or more embodiments of the present invention, the “binder 41” corresponds to an example of the “binder” in one or more embodiments of the present invention, the “conductive particles 42” correspond to an example of the “conductive particles” in one or more embodiments of the present invention, and the “soft resin 50” corresponds to an example of the “soft resin” in one or more embodiments of the present invention.

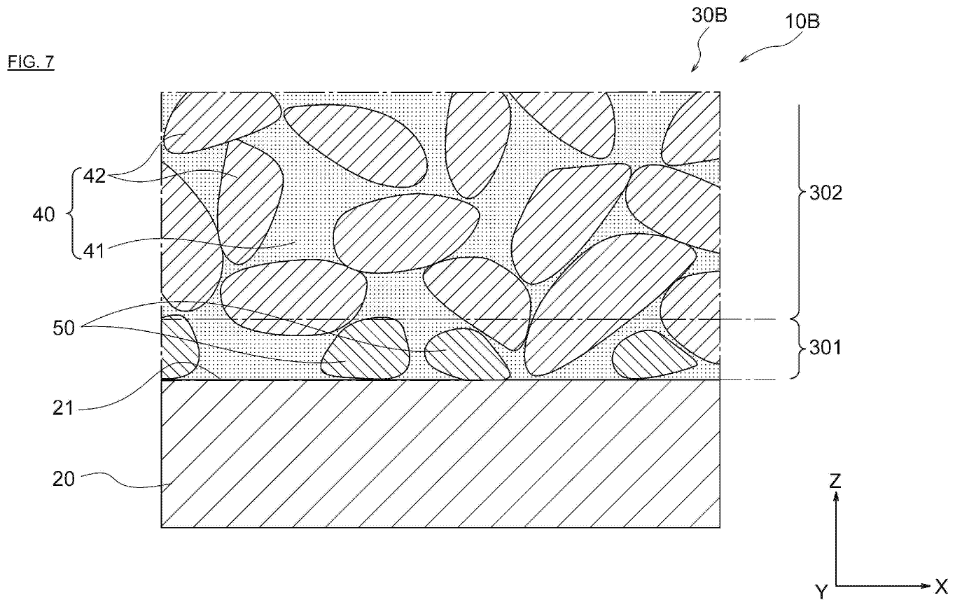

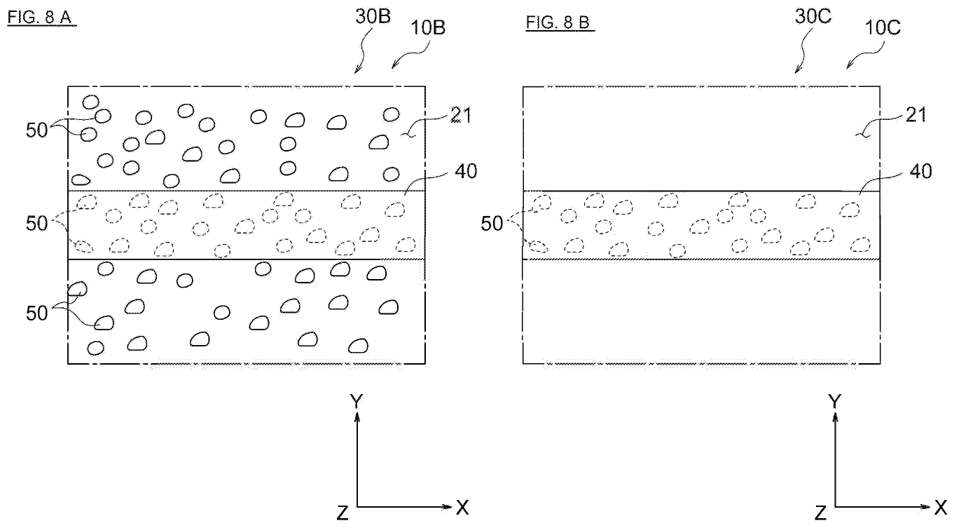

FIG. 7 is a cross-sectional view of a stretchable board according to one or more embodiments of the present invention taken in a height direction, FIG. 8A is a plan view illustrating the stretchable board according to one or more embodiments of the present invention, and FIG. 8B is a plan view illustrating a modified example of the stretchable board according to one or more embodiments of the present invention. The same configurations as those in the aforementioned embodiments are denoted with the same reference numerals, the duplicative description thereof is omitted, and the description in the aforementioned embodiments is applicable.

In a stretchable board 10B illustrated in FIG. 7, a stretchable wiring body 30B includes a first region 301 in which the soft resin 50 exists and a second region 302 in which the abundance ratio of the soft resin 50 is lower than that in the first region 301.

The first region 301 is disposed to correspond to a region in which a difference in stretching properties between the stretchable substrate 20 and the conductor part 40 (for example, an interface between the stretchable substrate 20 and the conductor part 40), such as the vicinity of the main surface 21 of the stretchable substrate 20. The second region 302 is disposed to correspond to a region other than the first region 301 in the conductor part 40 in which it is difficult to generate a difference in stretching properties. In one or more embodiments of the present invention, the first region 301 and the second region 302 are laid in the order from a side close to the stretchable substrate 20 along the height direction of the stretchable wiring body 30B.

Particularly, in one or more embodiments of the present invention, since the abundance ratio of the soft resin 50 in the second region 302 is set to 0%, that is, the soft resins 50 do not exist in the second region 302, the abundance ratio of the soft resin 50 in the second region 302 is lower than the abundance ratio of the soft resin 50 in the first region 301. The abundance ratio of the soft resin 50 in the second region 302 may be set to be higher than 0% and lower than the abundance ratio of the soft resin 50 in the first region 301.

This soft resins 50 are dispersed on the main surface 21 of the stretchable substrate 20. In one or more embodiments of the present invention, as illustrated in FIG. 8A, a plurality of soft resins 50 are uniformly disposed on the whole region of the main surface 21 of the stretchable substrate 20, but the present invention is not particularly limited thereto. The plurality of soft resins 50 may be disposed to correspond only to a region where the conductor part 40 is provided on the main surface 21 of the stretchable substrate 20 as in a stretchable board 10C (stretchable wiring body 30C) illustrated in FIG. 8B.

Such a stretchable board 10B can be produced by the following method. That is, first, a solution formed by mixing the soft resin 50 with water or solvent and various is applied onto the main surface 21 of the stretchable substrate 20 and the solution is dried. Then, the aforementioned conductive paste is applied onto the main surface 21 on which the soft resin 50 remains, and the conductive paste is cured to form the conductor part 40. Through the above operation, the stretchable board 10B can be obtained.

As described above, in one or more embodiments of the present invention, as a conductive paste forming the conductor part 40, the conductive paste in which the soft resins 50 are not dispersed can be used, and thus various conductive pastes can be easily used in accordance with requests to the stretchable board 10.

Further, in one or more embodiments of the present invention, since the soft resins 50 are disposed to correspond to the interface between the stretchable substrate 20 and the conductor part 40 in which a difference in expansibility is easy to occur, it is difficult to generate cracks due to the difference in expansibility in the interface. According to this, the durability of the stretchable board 10B can be improved.

In one or more embodiments of the present invention, the soft resins are not dispersed in the binder 41 of the conductor part 40, but the present invention is not particularly limited thereto. That is, the soft resins 50 may be disposed to correspond to an interface between the stretchable substrate 20 and the conductor part 40, and the granular soft resins may be dispersed in the binder 41 of the conductor part 40.

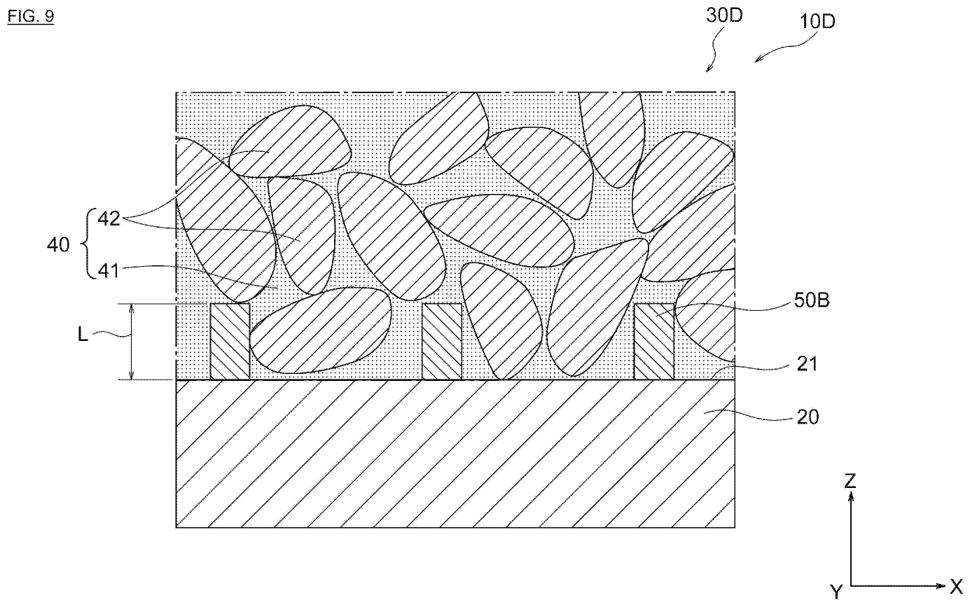

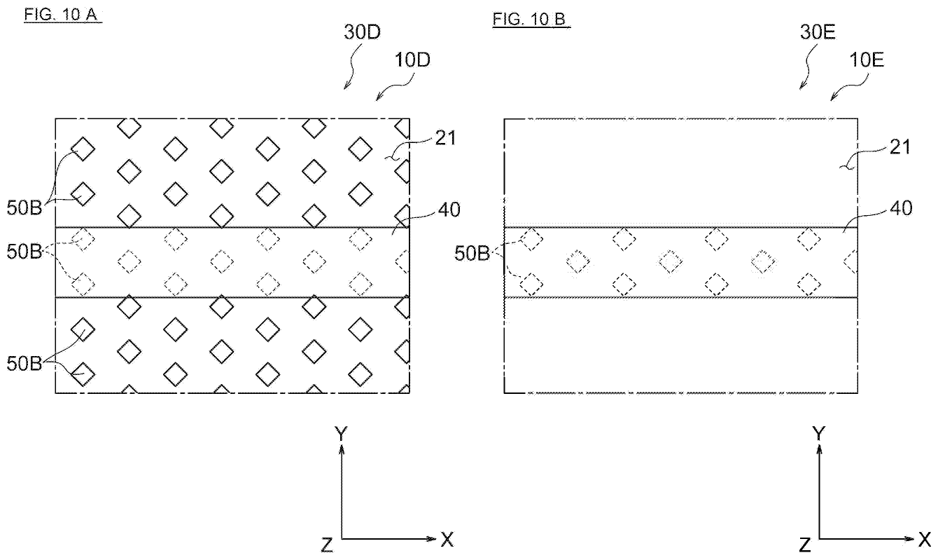

FIG. 9 is a cross-sectional view of a stretchable board according to still one or more embodiments of the present invention taken in a height direction, FIG. 10A is a plan view illustrating the stretchable board according to still one or more embodiments of the present invention, and FIG. 10B is a plan view illustrating a modified example of the stretchable board according to still one or more embodiments of the present invention. The same configurations as those in the aforementioned embodiments are denoted with the same reference numerals, the duplicative description thereof is omitted, and the description in the aforementioned embodiments is applicable.

In a stretchable board 10D illustrated in FIG. 9, a soft resin 50B of a stretchable wiring body 30D is formed in the form of a prismatic column having a substantially square cross-section. This soft resin 50B is provided directly on the main surface 21 of the stretchable substrate 20 and protrudes towards a side away from the main surface 21.

A plurality of soft resins 50B are arranged in zigzags in plan view as illustrated in FIG. 10A. The arrangement method of the plurality of soft resins 50B is not particularly limited to the above description, and the plurality of soft resins 50B may be arranged in the form of a grating or randomly arranged. Further, in one or more embodiments of the present invention, the plurality of soft resins 50B are disposed uniformly on the whole region of an upper surface 21 (main surface 21), but the present invention is not particularly limited thereto. The plurality of soft resins 50 may be disposed to correspond only to a region where the conductor part 40 is provided on the main surface 21 of the stretchable substrate 20 as in a stretchable board 10E (stretchable wiring body 30E) illustrated in FIG. 10B. Further, on the upper surface 21, the soft resins 50B may be arranged while regions having different arrangement densities of the soft resins 50B are mixed.

The conductor part 40 is formed to cover this soft resin 50B by applying and curing a conductive paste. According to this, the soft resin 50B having a prismatic column shape is embedded in the binder 41. As illustrated in FIG. 9, the length L of the soft resin 50B is smaller than a height H (see FIG. 2) of the conductor part 40 (H>L) according to one or more embodiments of the present invention. Further, the length L of the soft resin 50B is smaller than the particle diameter D (see FIG. 4) of the conductive particle 42 (D>L) according to one or more embodiments of the present invention. Since the soft resin 50B of one or more embodiments of the present invention has a sufficiently large aspect ratio, the length of the soft resin 50B in the height direction approximates the length L of the soft resin 50B.

Such a soft resin 50B may be formed by applying a soft resin composition onto the main surface 21 using a method such as a dispensing method, an ink jet method, or a screen printing method and curing the soft resin composition. Alternatively, the soft resin 50B may be formed by pressing a plate (not illustrated) against the main surface 21 of the stretchable substrate 20 using an imprinting method. In this case, the soft resin 50B is a protrusion which is a protruding portion of the stretchable substrate 20, and the stretchable substrate 20 and the soft resin 50B are integrally formed with each other.

In such a stretchable board 10D, the arrangement of the plurality of soft resins 50B can be set in advance. Herein, when the abundance ratio of the soft resin 50 in the stretchable wiring body 30D is increased, the stretching properties of the conductor part 40 tend to be accordingly improved and the durability of the conductor part 40 tends to be degraded; on the other hand, when the abundance ratio of the soft resin 50 in the binder 41 is decreased, the stretching properties of the conductor part 40 tend to be accordingly degraded and the durability of the conductor part 40 tends to be improved. In this case, for example, since the conductor part 40 are required high stretching properties in a region where the deformation amount of the stretchable board 10D is large, the soft resins 50B exist in a large amount; on the other hand, since the conductor part 40 is required high durability rather than the stretching properties in a region where the deformation amount of the stretchable board 10D is small, the soft resins 50B exist in a small amount. According to this, in the stretchable board 10D, both the stretching properties and the durability of the conductor part 40 can be improved in accordance with requests.

Although the soft resins are not dispersed in the binder 41 of the conductor part 40 in one or more embodiments of the present invention, the present invention is not limited thereto. That is, the soft resins 50B may be provided directly on the main surface 21 of the stretchable substrate 20, and the granular soft resins may be dispersed in the binder 41 of the conductor part 40. In this case, each of the soft resins 50B that are at least a part of the soft resins may be a protrusion at which a protruding part of the stretchable substrate 20.

Embodiments heretofore explained are described to facilitate understanding of the present invention and are not described to limit the present invention. It is therefore intended that the elements disclosed in the above embodiments include all design changes and equivalents to fall within the technical scope of the present invention.

For example, although the conductor part 40 is provided directly on the stretchable substrate 20 in the aforementioned embodiments, the present invention is not particularly limited thereto, and an interposed layer may be present between the stretchable substrate 20 and the conductor part 40. As a material constituting this interposed layer, for example, a polyester resin, a polyurethane resin, an acrylic resin, a silicon resin, and the like can be used. One or a plurality of such an interposed layer may be laid between the stretchable substrate 20 and the conductor part 40.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE NUMERALS

10 STRETCHABLE BOARD

20 STRETCHABLE SUBSTRATE

21 MAIN SURFACE

30 STRETCHABLE WIRING BODY

301 FIRST REGION

302 SECOND REGION

40 CONDUCTOR PART

41 BINDER

42 CONDUCTIVE PARTICLE

50 SOFT RESIN

1. A stretchable wiring body comprising:
a conductor that comprises a binder and conductive particles dispersed in the binder; and
soft resins that are embedded in the binder and are softer than the binder, wherein
the conductive particles are not covered with the soft resins.

2. The stretchable wiring body according to claim 1, wherein the following Formula (1) is satisfied:
D>L (1)
where
D is a particle diameter of each of the conductive particles, and
L is a length of each of the soft resins.

3. The stretchable wiring body according to claim 1, wherein each of the soft resins has a granular shape.

4. The stretchable wiring body according to claim 3, wherein the soft resins are dispersed in the binder.

5. A stretchable board comprising:
the stretchable wiring body according to claim 1; and
a stretchable substrate on which the conductor is disposed.

6. The stretchable board according to claim 5, wherein at least some of the soft resins are protrusions that protrude from the stretchable substrate.
